(19) United States
(12) Patent Application Publication
(10) Pub. No.: US 2026/0024725 A1
(43) Pub. Date: Jan. 22, 2026

(54) GAS SUPPLY APPARATUS AND SUBSTRATE PROCESSING APPARATUS

(71) Applicant: NISSIN ION EQUIPMENT CO., LTD., Koka-city (JP)

(72) Inventors: Takumi SATO, Koka-city (JP); Koyu UENO, Koka-city (JP)

(73) Assignee: NISSIN ION EQUIPMENT CO., LTD., Koka-city (JP)

(21) Appl. No.: 19/263,884

(22) Filed: Jul. 9, 2025

(30) Foreign Application Priority Data
Jul. 20, 2024 (JP) 2024-116592

(51) Int. Cl. H01J 37/32

(52) U.S. Cl. CPC H01J 37/3244; H01J 37/32412

(57) ABSTRACT

A gas supply apparatus includes a housing including a first cabinet, and one or more partition walls that divides an inside of the first cabinet into a first container compartment and a flow path compartment. The first container compartment houses a first container that stores a first gas, and the flow path compartment houses a first flow path through which the first gas flows to an outside of the gas supply apparatus and a second flow path through which a second gas flows to the outside of the gas supply apparatus, the second gas being different from the first gas. The inside of the housing is configured to be forcibly exhausted to an outside of the housing.

### CROSS-REFERENCE TO RELATED APPLICATION

This application claims priority from Japanese Patent Application No. JP 2024-116592, filed in the Japanese Patent Office on Jul. 20, 2024, the disclosure of which being incorporated by reference herein in its entirety.

### BACKGROUND

### 1. Field

Various embodiments are related to a gas supply apparatus that supplies a plurality of types of gases to a plasma generating chamber, and a substrate processing apparatus having a gas supply apparatus.

### 2. Description of Related Art

In a semiconductor manufacturing process, a substrate processing apparatus having a plasma generating chamber, such as an ion implantation apparatus or a plasma substrate processing apparatus, is used. Such a substrate processing apparatus generally includes a gas supplying apparatus for supplying a source gas or the like to a plasma generating chamber.

### SUMMARY

It is an aspect to suppress contact of a combustible gas or a corrosive gas with a device constituting a flow path in a situation where the gas leaks from the flow path.

According to an aspect of one or more embodiments, there is provided a gas supply apparatus for supplying a plurality of types of gases to a plasma generation chamber in which plasma is generated, the gas supply apparatus comprising a housing comprising a first container accommodating compartment that in configured to receive a first container that stores a first gas having flammability or corrosiveness; a flow path accommodating compartment that accommodates a first flow path through which the first gas flows to an outside of the gas supply apparatus and a second flow path through which a second gas flows to the outside of the gas supply apparatus, the second gas being different from the first gas; and one or more partition walls that partition an inside of the housing into a plurality of compartments including the first container accommodating compartment and the flow path accommodating compartment. Both the first container accommodating compartment and the flow path accommodating compartment are configured to be forcibly evacuated.

According to another aspect of one or more embodiments, there is provided a gas supply apparatus comprising a housing comprising a first cabinet; and at least one partition wall that divides an inside of the first cabinet into a first container compartment and a flow path compartment. The first container compartment is configured to house a first container that stores a first gas, and the flow path compartment being configured to house a first flow path through which the first gas flows to an outside of the gas supply apparatus and a second flow path through which a second gas flows to the outside of the gas supply apparatus, the second gas being different from the first gas. The inside of the housing is configured to be forcibly exhausted to an outside of the housing.

### BRIEF DESCRIPTION OF DRAWINGS

FIG. 1 is a schematic view showing a gas supply apparatus and a substrate processing apparatus according to an embodiment.

FIG. 2 is a perspective view showing a gas supply apparatus according to an embodiment.

FIG. 3 is a front view showing a gas supply apparatus in a state in which a partition member is removed, according to an embodiment.

FIG. 4 is a vertical cross-sectional view of a gas supply apparatus taken along a line X1 to X1 in FIG. 3, according to an embodiment.

FIG. 5 is a front view showing a gas supply apparatus in a state in which a partition member is attached thereto, according to an embodiment.

FIG. 6 is a vertical cross-sectional view of a gas supply apparatus taken along a line X2 to X2 in FIG. 4, according to an embodiment.

FIG. 7 is a schematic view schematically showing a gas supply apparatus according to an embodiment.

### DETAILED DESCRIPTION

A gas supply apparatus used in a substrate processing apparatus such as an ion implantation apparatus supplies a plurality of types of gases to a plasma generating chamber. When such a gas supply apparatus supplies a combustible gas to the plasma generating chamber, it is advantageous to prevent the combustible gas from coming into contact with a device that potentially becomes an ignition source in a situation in which the combustible gas leaks.

In addition, in a case where such a gas supply apparatus supplies a corrosive gas to the plasma generating chamber, it is also useful that, in a situation where the corrosive gas leaks, the corrosive gas is prevented from coming into contact with the device, and corrosion of the device is suppressed.

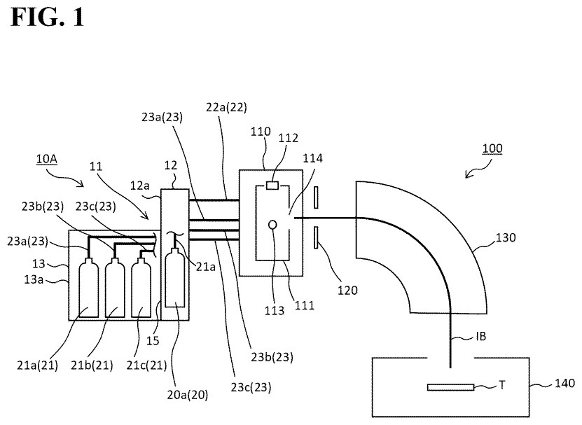

A gas supply apparatus 10A in an embodiment and a substrate processing apparatus 100 including the gas supply apparatus 10A are disclosed. Note that FIGS. 1 to 7 are created for the purpose of understanding the various embodiments, and the shapes, ratios of length dimensions, and ratios of scales of the respective components in the respective drawings are schematic and not necessarily made to scale or to coincide with each other.

FIG. 1 is a diagram schematically showing a gas supply apparatus 10A and a substrate processing apparatus 100 including the gas supply apparatus 10A, according to an embodiment.

In an embodiment, the substrate processing apparatus 100 includes a gas supply apparatus 10A, an ion source 110, a mass analysis magnet 130 and a processing chamber 140. The substrate processing apparatus 100 includes a plasma generating chamber 111 and performs a predetermined process on a target T. Specifically, the substrate processing apparatus 100 illustrated in FIG. 1 is an ion implantation apparatus that is used in a semiconductor manufacturing process and performs ion implantation on a target T, for example, a wafer.

As shown in FIG. 1, the ion source 110 includes the plasma generating chamber 111, and an extraction electrode 120 for extracting an ion beam IB from the ion source 110. The mass analysis magnet 130 separates ions included in the ion beam IB according to mass and allows the ions to pass therethrough. The processing chamber 140 in configured to receive the target T, and the ion beam IB having passed through the mass analysis magnet 130 is introduced into the processing chamber 140.

The gas supply apparatus 10A supplies a plurality of types of gases to the plasma generating chamber 111. The gas supply apparatus 10A can switch the type of gas supplied to the plasma generating chamber 111, and can also supply two or more types of gas to the plasma generating chamber 111 at the same time.

The ion source 110 includes the plasma generating chamber 111 and a cathode 112 that is heated to supply thermoelectrons to the plasma generating chamber 111. Further, the plasma generating chamber 111 is formed with a gas inlet 113 for introducing a gas supplied from the gas supply apparatus 10A into the plasma generating chamber 111, and an extraction opening 114 for extracting the ion beam IB to the outside of the ion source 110.

In the plasma generating chamber 111, plasma is generated from a source gas introduced from the gas inlet 113 and the thermoelectrons emitted from the cathode 112. Then, the ion beam IB is extracted from the plasma generated in the plasma generating chamber 111 through the extraction opening 114 by driving the extraction electrodes 120. The ion beam IB extracted from the plasma generating chamber 111 is mass-separated while passing through the mass analysis magnet 130, and the ion beam IB including predetermined ions is guided to the processing chamber 140.

The target T is disposed in the processing chamber 140. The ion beam IB is irradiated to the target T in the processing chamber 140, and thus, the ion implantation is performed on the target T.

The substrate processing apparatus 100 illustrated in FIG. 1 has the same configuration as that of an ion implantation device generally used in a semiconductor-manufacturing process, except that the substrate processing apparatus 100 includes the gas supply apparatus 10A. The gas supply apparatus 10A is descried in more detail below. Further description of the substrate processing apparatus 100 is omitted for conciseness.

The substrate processing apparatus 100 is not limited to the ion implantation apparatus. The substrate processing apparatus 100 may be any apparatus as long as the apparatus includes a plasma generating chamber in which plasma is generated. For example, in an embodiment, the substrate processing apparatus 100 may be a plasma substrate processing apparatus that irradiates the target T with plasma generated in the plasma generating chamber 111 without mass separation. In various embodiments, the substrate processing apparatus 100 may perform surface treatment of a metal material, a plastic material, or the like using plasma or the ion beam IB. That is, the target T is not limited to a wafer, and in some embodiments, the target T may be a metal material or a plastic material, or the like.

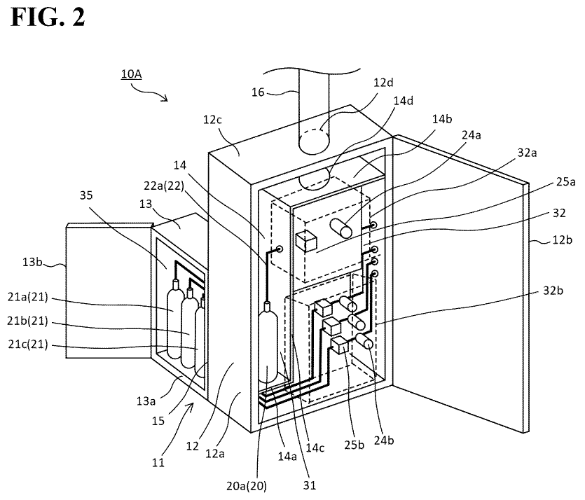

FIG. 2 is a perspective view of the gas supply apparatus 10A, according to an embodiment.

As shown in FIGS. 1 and 2, the gas supply apparatus 10A includes a housing 11 comprising a first cabinet 12 and a second cabinet 13. As shown in FIG. 2, the first cabinet 12 has a rectangular parallelepiped shape as a whole.

The first cabinet 12 includes a first main body 12a and a first door 12b. A surface of the first main body 12a has an opening, and the first door 12b opens and closes the opening. The second cabinet 13 is formed in a rectangular parallelepiped shape as a whole. The second cabinet 13 includes a second main body 13a and a second door 13b. A surface of the second main body 13a has an opening, and the second door 12b opens and closes the opening.

When the side of the first main body 12a on which the opening is formed is regarded as the front of the first main body 12a and the side of the second main body 13a on which the opening is formed is regarded as the front of the second main body 13a, the housing 11 is configured such that a wall portion serving as the back surface of the first main body 12a and a wall portion serving as the side surface of the second main body 13a are in contact with each other. However, embodiments are not limited to this configuration. In some embodiments, the housing 11 may be configured as a single integrated housing such that a single wall portion of the housing serves as both the back surface of the first main body 12a and the side surface of the second main body 13a.

The gas supply device 10A includes a first container 20 for storing a first gas having combustibility or corrosiveness, and three second containers 21 for storing a second gas which is a gas species different from the first gas. While one first container 20 and three second containers 21 are illustrated for purposes of description, the number of the first container 20 and the number of the second container 21 included in the gas supply apparatus 10A are not limited to the specific numbers illustrated.

The first gas may be a gas having combustibility, and may be, for example, a hydrogen gas. The second gas may be a gas that is not combustible, and may be, for example, a BF₃ gas, a PF₃ gas, or a PH₃ gas. Hereinafter, in order to facilitate understanding, the first gas may be referred to as a combustible gas, and the second gas may be referred to as a non-combustible gas.

The first container 20 included in the gas supply apparatus 10A may be referred to as a combustible gas cylinder 20a, and the three second containers 21 may be referred to as a first incombustible gas cylinder 21a, a second incombustible gas cylinder 21b, and a third incombustible gas cylinder 21c, respectively. Further, the respective incombustible gases stored in the first incombustible gas cylinder 21a, the second incombustible gas cylinder 21b, and the third incombustible gas cylinder 21c may be referred to as a first incombustible gas, a second incombustible gas, and a third incombustible gas, respectively. In an embodiment, the first, second and third incombustible gasses may be the same. In some embodiments, at least one of the first, second, or third incombustible gasses may be different from remaining ones of the gasses. In some embodiments, each of the first, second, and third incombustible gasses may be different from the others.

The first container 20 and the second container 21 are not limited to gas cylinders. For example, when the first gas is hydrogen, the first container 20 may be a container containing a hydrogen storage alloy therein.

The gas supply apparatus 10A includes a first flow path 22 having a first end connected to the first container 20 and a second end connected to the ion source 110. The first gas stored in the first container 20 flows through the first flow path 22 and is supplied to the plasma generating chamber 111 included in the ion source 110. In an embodiment, the first flow path 22 may be implemented by a hose or pipe. However, embodiments are not limited thereto.

The gas supply apparatus 10A includes three second flow paths 23, each of which has a first end connected to a corresponding one of the second containers 21 and a second end connected to the ion source 110. The second gas stored in each second container 21 flows through a corresponding second flow path 23 and is supplied to the plasma generating chamber 111. In FIGS. 1-2, the second flow paths 23 having first ends connected to the first incombustible gas cylinder 21a, the second incombustible gas cylinder 21b, and the third incombustible gas cylinder 21c, respectively, may be referred to as a first incombustible gas flow path 23a, a second incombustible gas flow path 23b, and a third incombustible gas flow path 23c, respectively. In an embodiment, each of the first incombustible gas flow path 23a, the second incombustible gas flow path 23b, and the third incombustible gas flow path 23c may be implemented by a corresponding hose or pipe. However, embodiments are not limited thereto.

That is, the gas supply apparatus 10A of FIGS. 1-2 includes the first incombustible gas path 23a, the second incombustible gas path 23b, and the third incombustible gas path 23c, the first ends of which are connected to the first incombustible gas cylinder 21a, the second incombustible gas cylinder 21b, and the third incombustible gas cylinder 21c, respectively, and the second ends of which are connected to the ion source 110.

The first incombustible gas flows through the first incombustible gas flow path 23a and is supplied to the plasma generating chamber 111. The second incombustible gas and the third incombustible gas flow through the second incombustible gas flow path 23b and the third incombustible gas flow path 23c, respectively, and are supplied to the plasma generating chamber 111.

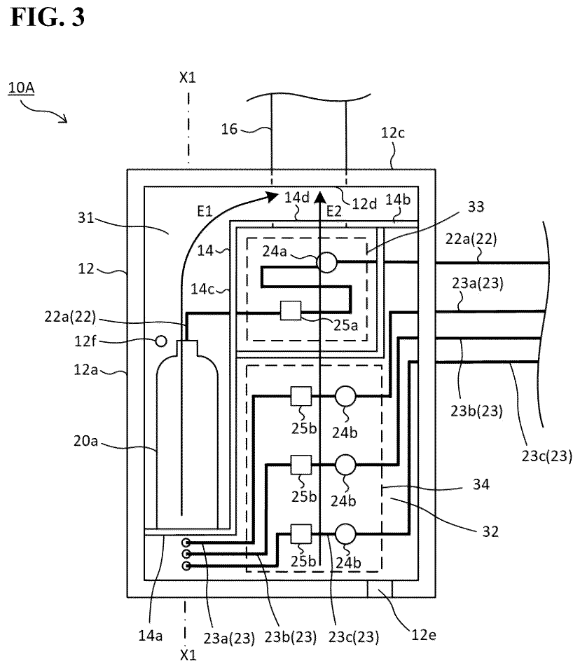

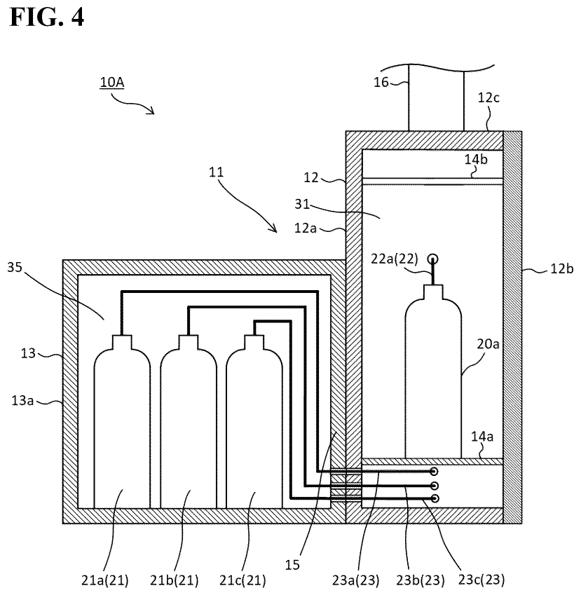

FIG. 3 is a front view of the gas supply apparatus 10A, according to an embodiment. FIG. 4 is a vertical cross-sectional view of a gas supply apparatus taken along a line X1 to X1 in FIG. 3, according to an embodiment. FIG. 3 shows a state in which a partition member 17 described later is removed. As shown in FIGS. 2-4, the gas supply device 10A has a first container accommodating compartment 31 for accommodating the first container 20. The first container accommodating compartment 31 is formed by partitioning the inside of the first main body side 12a by a first partition wall 14 described later.

The gas supply apparatus 10A has a flow path accommodating compartment 32 that houses a partial region of the first flow path 22 and a partial region of each second flow path 23. The flow path accommodating compartment 32 is formed by partitioning the inside of the first main body side 12a by the first partition wall 14. The first container accommodating compartment 31 and the flow path accommodating compartment 32 are partitioned by the first partition wall 14. To be specific, the flow path accommodating compartment 32 illustrated in FIGS. 2-4 houses a partial region of the combustible gas flow path 22, a partial region of the first incombustible gas flow path 23a, a partial region of the second incombustible gas flow path 23b, and a partial region of the third incombustible gas flow path 23c.

As shown in FIGS. 1 and 2, the gas supply apparatus 10A includes a second container accommodating compartment 35 for accommodating the second containers 21, that is, a first incombustible gas cylinder 21a, a second incombustible gas cylinder 21b, and a third incombustible gas cylinder 21c.

The second container accommodating compartment 35 is formed by partitioning the internal space of the housing 11 by a second partition wall 15.

The second container accommodating compartment 35 in FIGS. 2-4 is formed by the second main body 13a. The second partition wall 15 in FIGS. 2-4 is a wall portion that brings the first main body 12a and the second main body 13a into contact with each other.

In FIGS. 2-4, the back surface of the first main body 12a and the side surface of the second main body 13a are in contact with each other, so that the first main body 12a and the second main body 13a are substantially integrated to constitute the housing 11. Therefore, it is considered that the internal space of the first main body side 12a and the internal space of the second main body side 13a are formed by partitioning the internal space of the housing 11 by a wall portion that brings the first main body 12a and the second main body 13a into contact with each other.

As shown in FIGS. 2 and 3, the first partition wall 14 is constituted by a bottom 14a, a top 14b, and a side 14c. The combustible gas cylinder 20a is disposed on the bottom 14a. The top 14b is disposed so as to face a top portion 12c of the first main body 12a. The side 14c is disposed along the vertical direction and connects the bottom 14a and the top 14b.

The gas supply apparatus 10A includes an exhaust duct 16. The exhaust duct 16 is connected to a first vent hole 12d formed in the top portion 12c. A first through hole 12e is formed in the bottom of the first main body 12a to allow gas to flow in from the outside of the housing 11. The gas supply apparatus 10A is configured to forcibly exhaust the inside of the housing 11 through the exhaust duct 16 while the gas supply apparatus 10A is operating, such that the inside of the first container accommodating compartment 31 and the inside of the flow path accommodating compartment 32 both become negative pressure.

More specifically, while the gas supply apparatus 10A is operating, the gas in the first container accommodating compartment 31 flows along a first evacuation path E1 from below toward the first vent hole 12d and is forcibly discharged through the first vent hole 12d.

A second vent hole 14d is formed in the top 14b of the first partition wall 14. The second vent hole 14d is positioned below the first vent hole 12d. Therefore, while the gas supply apparatus 10A is operating, the gas in the flow path accommodating compartment 32 flows through a second evacuation path E2 from the lower side to the upper side, passes through the second vent hole 14d and the first vent hole 12d in order, and is then forcibly discharged to the outside through the exhaust duct 16. In an embodiment, the second evaluation path E2 may be fluidly separated from the first evacuation path E1 by the first partition wall 14, such that the first evacuation path E1 is separately forcibly evacuated through the exhaust duct 16 from the forcible evacuation of the second evacuation path E2 through the exhaust duct 16.

A second through hole 12f that allows the internal space of the first container accommodating compartment 31 and the internal space of the second container accommodating compartment 35 to communicate with each other may be formed in the second partition wall 15.

In this case, the inside of the second container accommodating compartment 35 is also set to a negative pressure. That is, the gas in the second container accommodating compartment 35 enters the first container accommodating compartment 31 through the second through hole 12f, and is then forcibly discharged to the outside through the exhaust duct 16.

As shown in FIGS. 2 and 3, the flow path accommodating compartment 32 has a first flow path region 33 in which a part of the first flow path 22, that is, a part of a combustible gas flow path 22a in FIGS. 1-3 is collected. The flow path accommodating compartment 32 has a second flow path region 34 in which a part of the second flow paths 23, that is, a part of the first incombustible gas flow path 23a, the second incombustible gas flow path 23b, and the third incombustible gas flow path 23c in FIGS. 1-3 are collected.

The gas supply apparatus 10A comprises at least one first device 24a that forms part of the combustible gas flow path 22 and is a potential source of ignition. The gas supply apparatus 10A comprises at least one second device 24b that forms part of the second flow paths 23 and is a potential source of ignition. In FIGS. 1-3, each of the three second flow paths 23, that is, the first incombustible gas flow path 23a, the second incombustible gas flow path 23b, and the third incombustible gas flow path 23c, includes at least one second device 24b.

The first device 24a and the second device 24b are devices that generate static charges during operation, and may be, for example, mass flow controllers that control gas flow rates or pressure sensors that monitor gas pressures in pipes. The first device 24a and the second device 24b are not limited to mass flow controllers or pressure sensors, and in some embodiments, may be, for example, pressure switches, flow meters, electromagnetic valves, or electric valves.

In FIGS. 1-3, the first device 24a constituting a part of the first flow path 22 is disposed so as to be entirely included in the first flow path region 33. That is, all potential ignition sources that form part of the first flow path 22 are within the first flow path region 33.

Further, the at least one second device 24b constituting a part of the second flow path 23 is arranged so as to be entirely included in the second flow path region 34. That is, all potential ignition sources that form part of the second flow path 23 are within the second flow path region 34.

The flow path accommodating compartment 32 may be considered to be divided into the first flow path region 33 in which one or a plurality of the first device 24a are disposed so as to be integrated and the second flow path region 34 in which one or a plurality of the second device 24b are disposed so as to be integrated.

In FIGS. 1-3, the first flow path region 33 is located downstream of the second flow path region 34 in an evacuation path through which the flow path accommodating compartment 32 is evacuated. That is, the first flow path region 33 is located above the second flow path region 34.

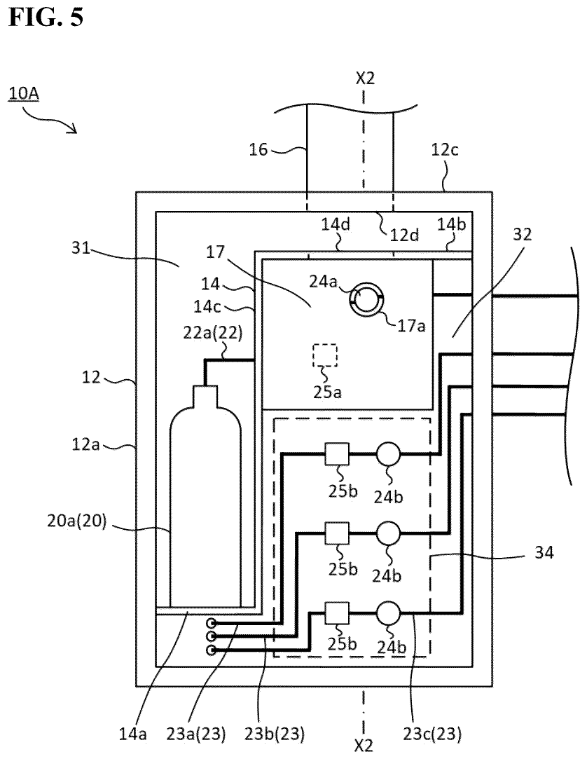

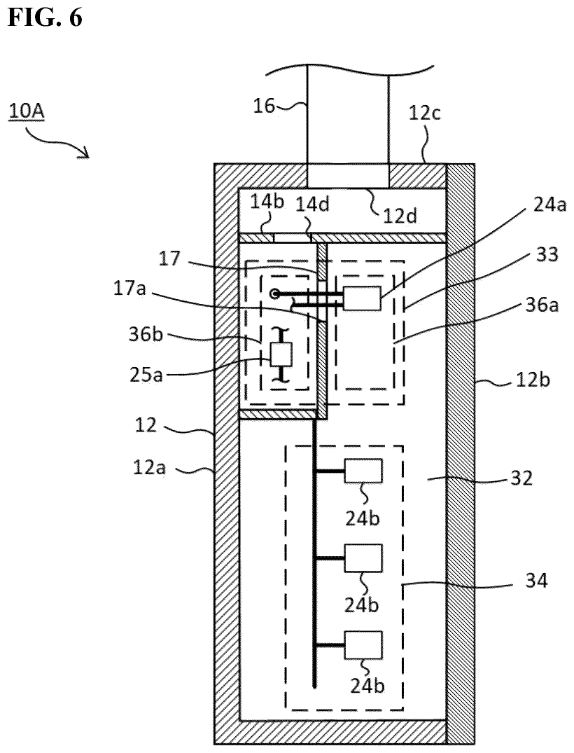

FIG. 5 is a front view showing the gas supply apparatus 10A in a state in which the partition member 17 is attached thereto, according to an embodiment. FIG. 6 is a vertical cross-sectional view of the gas supply apparatus 10A taken along a line X2 to X2 in FIG. 5, according to an embodiment.

As shown in FIGS. 5-6, the gas supply apparatus 10A further includes the partition part 17. In some embodiments, a plurality of the partition part 17 may be provided. The partition part 17 partitions the first flow path region 33 into a device arrangement region 36a and a device non-arrangement region 36b (best seen in FIG. 6). The device arrangement area 36a is an area in which the first device 24a is arranged. The device non-arrangement area 36b is an area in which the first device 24a is not arranged.

In FIGS. 5-6, the partition part 17 is disposed along the vertical direction. The device arrangement region 36a is formed on the opening side of the first main body 12a, and the device non-arrangement region 36b is formed on the back surface side of the first main body 12a.

In FIGS. 5-6, the partition part 17 is a plate, and is attachable to and detachable from the housing 11. The partition part 17 is formed with a through hole 17a for allowing the partition member 17 to be attached and detached without interfering with the first device 24a.

In a state in which the first door 12b is opened, the inside of the first main body 12a, that is, the first container accommodating compartment 31 and the flow path accommodating compartment 32 are exposed to the outside. Therefore, the operator can perform operations such as replacement of the first container 20 (e.g., the combustible gas cylinder 20a), inspection and replacement of parts of the pipes or hoses constituting the second flow paths 23 (the first incombustible gas flow path 23a, the second incombustible gas flow path 23b, and the third incombustible gas flow path 23c), the first device 24a, the second device 24b, and the like.

In this case, in a state in which the first door 12b is opened, the device arrangement region 36a is on the opening side of the first main body 12a, and thus the operator can perform work such as inspection or replacement of the first device 24a. On the other hand, the presence of the partition part 17 prevents the operator from inspecting or replacing a member present in the device non-arrangement region 36b.

Therefore, when the operator performs work such as inspection or replacement of a member present in the device non-arrangement region 36b, the partition part 17 is first removed. After the operation, the partition part 17 is reattached to the housing 11 again.

The first flow path 22 and the second flow path 23 are each formed by connecting a plurality of pipes or hoses by a plurality of joints. FIGS. 2 to 4 schematically illustrate a first joint 25a that is a joint in the first flow path 22 and a second joint 25b that is a joint in the second flow path 23. In an embodiment, the first flow path 22 may include a plurality of the first joint joints 25a, but only one first joint 25a is shown in FIGS. 2 to 4 for clarify and conciseness. Similarly, in an embodiment, each second flow path 23 may include a plurality of the second joint joints 25b, but only one second joint 25b is shown in FIGS. 2 to 4 for clarify and conciseness.

As shown in FIGS. 5-6, the gas supply apparatus 10A is configured such that all the first joints 25a disposed in the flow path accommodating compartment 32 are present in the device non-arrangement region 36b in which the first device 24a is not disposed.

The second vent hole 14d is positioned above the device non-arrangement region 36b, and the gas in the flow path accommodating compartment 32 always passes through the through hole 17a of the partition part 17, the second vent hole 14d, and the first vent hole 13d in this order, and then is discharged to the outside through the exhaust duct 16.

Therefore, for example, any of the combustible gas leaking from the first joint 25a is discharged to the outside through the second vent hole 14d without entering the device arrangement region 36a in which the first device 24a is disposed. Therefore, even if the combustible gas leaks from the first joint 25a, the gas is prevented from coming into contact with the first device 24a and the second device 24b which could ignite the combustible gas, so that the gas supply apparatus 10A and the substrate processing apparatus 100 are secured.

In the gas supply apparatus 10A and the substrate processing apparatus 100, the first container accommodating compartment 31 in which the first container 20 is accommodated and the flow path accommodating compartment 32 in which a part of the first flow path 22 and a part of the second flow paths 23 are accommodated are formed by partitioning the inside of the first main body 12a of the housing 11 by the first partition wall 14.

While the gas supply apparatus 10A is operating, the first container accommodating compartment 31 and the flow path accommodating compartment 32 are kept at a negative pressure. The gas in the first container accommodating compartment 31 passes through the first vent hole 12d formed in the top portion 12c of the housing 11, and is then discharged to the outside through the exhaust duct 16. Therefore, for example, even when the first gas leaks from the first container 20 and disposed in the first container accommodating compartment 31, the gas does not enter the flow path accommodating compartment 32 and is discharged to the outside without remaining in first container accommodating compartment 31 because the first container accommodating compartment 31 is forcibly exhausted.

In the flow path housing chamber 32, for example, when the first gas leaks from the first joint 25a constituting the first flow path 22, the gas is discharged to the outside without remaining in the flow path accommodating compartment 32 as the flow path housing chamber 32 is forcibly exhausted.

When the first gas stored in the first container 20 is combustible, the leaked first gas does not enter the flow path accommodating compartment 32 from the first container accommodating compartment 31 and is discharged to the outside without entering in the flow path accommodating compartment 32 as described above, and thus the gas is prevented from coming into contact with the first device 24a and the second device 24b. Therefore, the safety of the gas supply apparatus 10A and the substrate processing apparatus 100 is enhanced.

The first gas stored in the first container 20 may be a corrosive gas. In this case, the leaked first gas is also prevented from coming into contact with the first device 24a and the second device 24b, and thus the first device 24a and the second device 24b are prevented from corroding. Examples of the corrosive gas include, but are not limited to, a gas containing chlorine and a gas containing fluorine.

In the gas supply apparatus 10A, the housing 11 is partitioned by a second partition wall 15 to form a second container accommodating compartment 35. Therefore, the combustible gas cylinder 20a, the combustible gas flow path 22a, the first incombustible gas flow path 23a, the second incombustible gas flow path 23b, the third incombustible gas flow path 23c, the first incombustible gas cylinder 21a, the second incombustible gas cylinder 21b, and the third incombustible gas cylinder 21c are accommodated in the first container accommodating compartment 31, the flow path accommodating compartment 32, and the second container accommodating compartment 35 formed by partitioning the inside of the housing 11.

In the gas supply apparatus 10A, the flow path accommodating compartment 32 is divided into a first flow path region 33 in which a part of the first flow path 22 is collected and a second flow path region 34 in which a part of the second flow path 23 (e.g., a part of the first incombustible gas flow path 23a, the second incombustible gas flow path 23b, and the third incombustible gas flow path 23c) is collected.

The first flow path region 33 is located downstream of the second flow path region 34 in the path through which the gas is exhausted from the flow path accommodating compartment 32. Further, flow path accommodating compartment 32 is forcibly exhausted from the exhaust duct 16 connected to the upper side of the first flow path region 33 in the path through which the flow path accommodating compartment 32 is exhausted.

Therefore, even if the first gas leaks from the first flow path region 33, the gas is discharged to the outside of the housing 11 from the exhaust duct 16 disposed above the housing 11 without passing through the second flow path region 34.

That is, any of the first gas that is leaked from the first flow path region 33 is prevented from entering the second flow path region 34 located on the upstream side of the exhaust path of the second flow path region 34. Therefore, in the case where the first gas is a combustible gas, the first gas is prevented from contacting the second device 24b and igniting. In addition, when the second gas is a corrosive gas, corrosion of the pipes and the second device 24b in the second flow path region 34 is suppressed.

In the gas supply apparatus 10A, the first flow path region 33 is partitioned by the partition part 17 into a device arrangement region 36a including the first device 24a and a device non-arrangement region 36b not including a potential ignition source.

Therefore, in a case where the first gas is a combustible gas, even when the first gas leaks in the device non-arrangement region 36b, the combustible gas is prevented from flowing to the device arrangement region 36a including a potential ignition source. Therefore, safety is further enhanced in the case where the first gas leaks from the first flow path 22.

Further, even when the first gas is a corrosive gas, the gas supply device 10A includes the partition part 17, and thus the first gas is prevented from coming into contact with the first device 24a and the second device 24b, and thus the corrosion of the first device 24a and the second device 24b is suppressed.

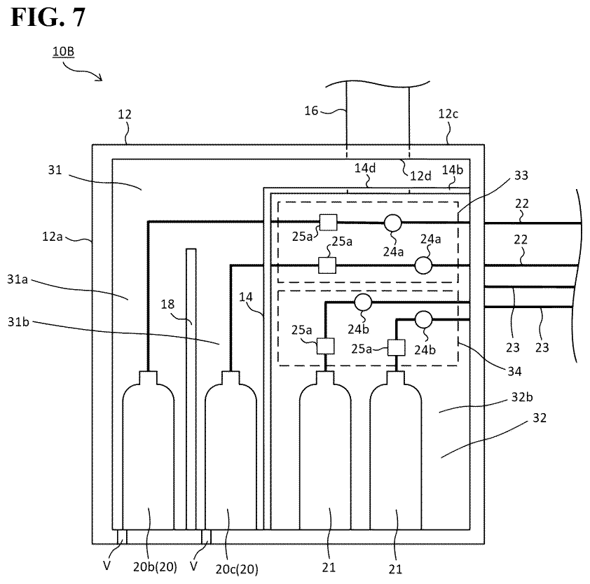

FIG. 7 is a diagram schematically showing a gas supply apparatus 10B, according to an embodiment.

In the gas supply apparatus 10B, all the first containers 20 and the second containers 21 are accommodated in the housing 11. Hereinafter, differences from the gas supply apparatus 10A will be described, and the same components as those of the gas supply apparatus 10A will be denoted by the same symbols as those of the gas supply apparatus 10A, and the description thereof will be omitted for conciseness.

As shown in FIG. 7, the gas supply apparatus 10B includes a third partition wall 18 that partitions the first container accommodating compartment 31 into two regions, in addition to the first partition wall 14. For example, the first container accommodating compartment 31 of the gas supply apparatus 10B has a first accommodating region 31a and a second accommodating region 31b which are formed by a third partition wall 18.

The first containers 20 are disposed in the first accommodating region 31a and the second accommodating region 31b, respectively. A combustible gas may be stored in the first container 20 disposed in the first accommodating region 31a, and a corrosive gas may be stored in the first container 20 disposed in the second accommodating region 31b. Hereinafter, the first container 20 disposed in the first accommodating region 31a may be referred to as a combustible gas container 20b, and the first container 20 disposed in the second accommodating region 31b may be referred to as a corrosive gas container 20c.

In an embodiment, the first containers 20 storing different corrosive gases may be disposed in the first accommodation region 31a and the second accommodation region 31b, respectively. For example, the first containers 20 disposed in the first accommodating region 31a may store a chlorine-containing gas, and the first containers 20 disposed in the second accommodating region 31b may store a fluorine-containing gas.

In FIG. 7, vent holes V are formed below the first accommodation region 31a and the second accommodation region 31b, and the gas in the first accommodation region 31a and the second accommodation region 31b passes through the first vent holes 13d and is forcibly discharged to the outside from the exhaust duct 16.

Two second containers 21 are housed in the flow path accommodating compartment 32, and the gas in the flow path accommodating compartment 32 passes through the second vent hole 14d and the first vent hole 12d in order and is forcibly discharged to the outside from the exhaust duct 16.

Two first flow paths 22, first ends of which are connected to the combustible gas container 20b and to the corrosive gas container 20c, are arranged in the flow path accommodating compartment 32 so that a part of the first flow paths 22 is collected in the first flow path region 33. The two second flow paths 23 connected to the two second containers 21 disposed in the flow path accommodating compartment 32 are disposed so that a part of the second flow paths 23 is collected in the second flow path region 34.

The first flow path region 33 is located on the downstream side of the second flow path region 34 in the exhaust path of the flow path accommodating compartment 32, and even when the first gas leaks in the flow path accommodating compartment 32, the gas is discharged to the outside without remaining in the flow path accommodating compartment 32. Therefore, the leaked first gas is prevented from coming into contact with the devices disposed in the flow path accommodating compartment 32.

While various embodiments have been shown and described above with respect to the drawings, various changes and modifications may be made thereto without departing from the spirit and scope of the present disclosure and all such changes and modification are intended to be included within the scope of the appended claims.

What is claimed is:

1. A gas supply apparatus for supplying a plurality of types of gases to a plasma generation chamber in which plasma is generated, the gas supply apparatus comprising:
a housing comprising:
a first container accommodating compartment that in configured to receive a first container that stores a first gas having flammability or corrosiveness;
a flow path accommodating compartment that accommodates a first flow path through which the first gas flows to an outside of the gas supply apparatus and a second flow path through which a second gas flows to the outside of the gas supply apparatus, the second gas being different from the first gas; and
one or more partition walls that partition an inside of the housing into a plurality of compartments including the first container accommodating compartment and the flow path accommodating compartment,
wherein both the first container accommodating compartment and the flow path accommodating compartment are configured to be forcibly evacuated.

2. The gas supply apparatus according to claim 1, wherein the one or more partition walls comprise a plurality of partition walls, and
the housing further includes a second container accommodating compartment that is defined by one or more of the plurality of partition walls and that is configured to house a second container that stores the second gas.

3. The gas supply apparatus according to claim 1, wherein:
the flow path accommodating compartment includes a first flow path region through which the first flow path passes and a second flow path region through which the second flow path passes,
the first flow path region is located inside the housing downstream from the second flow path region with respect to an evacuation path through which the flow path accommodating compartment is evacuated, and
the flow path accommodating compartment is forcibly exhausted from a downstream side of the first flow path region in the evacuation path.

4. The gas supply apparatus according to claim 3, wherein:
the first gas is a combustible gas;
the first flow path region is configured to house a first device that is a potential ignition source for the combustible gas; and
the second flow path region is configured to house a second device that is a potential ignition source for the combustible gas.

5. The gas supply apparatus according to claim 4, wherein the one or more partition walls comprising a plurality of partition walls, and
at least one of the plurality of partition walls partition the first flow path region into a first region in which the first device is disposed and a second region in which the first device is not disposed.

6. A substrate processing apparatus comprising:
the gas supply apparatus according to claim 1; and
a plasma generating chamber in which plasma is generated based on the first gas and the second gas supplied through the first flow path and the second flow path to the plasma generating chamber.

7. The gas supply apparatus according to claim 1, wherein:
the first gas is a combustible gas; and
the second gas is a non-combustible gas.

8. The gas supply apparatus according to claim 1, wherein each of the first flow path and the second flow path comprises a pipe or hose.

9. A gas supply apparatus comprising:
a housing comprising a first cabinet; and
at least one partition wall that divides an inside of the first cabinet into a first container compartment and a flow path compartment,
wherein the first container compartment is configured to house a first container that stores a first gas, and the flow path compartment being configured to house a first flow path through which the first gas flows to an outside of the gas supply apparatus and a second flow path through which a second gas flows to the outside of the gas supply apparatus, the second gas being different from the first gas,
wherein the inside of the housing is configured to be forcibly exhausted to an outside of the housing.

10. The gas supply apparatus according to claim 9, wherein the first container compartment is forcibly exhausted to the outside through a first evacuation path and the flow path compartment is forcibly exhausted to the outside through a second evacuation path that is fluidly separated from the first evacuation path by the at least one partition wall.

11. The gas supply apparatus according to claim 9, wherein the first cabinet comprises a vent hole in a top thereof, and the inside of the housing forcibly exhausted through the vent hole.

12. The gas supply apparatus according to claim 11, wherein the first container compartment is forcibly exhausted through the vent hole by a first evacuation path and the flow path compartment is forcibly exhausted through the vent hole a second evacuation path that is fluidly separated from the first evacuation path by the at least one partition wall.

13. The gas supply apparatus according to claim 12, wherein:
the flow path compartment includes a first flow path region through which the first flow path passes and a second flow path region through which the second flow path passes, and
the first flow path region is located inside the housing downstream from the second flow path region with respect to the second evacuation path.

14. The gas supply apparatus according to claim 9, wherein the at least one partition wall comprises a plurality of partition walls, and
wherein the housing further comprises a second cabinet that is defined by a partition wall of the plurality of partition walls and that is configured to house a second container that stores the second gas.

15. The gas supply apparatus according to claim 9, wherein:
the flow path compartment includes a first flow path region through which the first flow path passes and a second flow path region through which the second flow path passes,
the first flow path region is located inside the housing downstream from the second flow path region with respect to an evacuation path through which the flow path compartment is evacuated.

16. The gas supply apparatus according to claim 15, wherein:
the first gas is a combustible gas;
the first flow path region is configured to house a first device that is a potential ignition source for the combustible gas; and
the second flow path region is configured to house a second device that is a potential ignition source for the combustible gas.

17. The gas supply apparatus according to claim 16, wherein the at least one partition wall comprises a plurality of partition walls, and
a partition wall of the plurality of partition walls partitions the first flow path region into a first region in which the first device is disposed and a second region in which the first device is not disposed.

18. The gas supply apparatus according to claim 9, wherein:
the first gas is a combustible gas; and
the second gas is a non-combustible gas.
